(19) United States
(12) Patent Application Publication
(10) Pub. No.: US 2026/0123337 A1
(43) Pub. Date: Apr. 30, 2026

(54) WAFER CLEANING SYSTEM, WAFER DETECTING MODULE AND WAFER CLEANING METHOD

(71) Applicant: Taiwan Semiconductor Manufacturing Company, Ltd., Hsinchu (TW)

(72) Inventors: Yi-Chen Li, Taichung City (TW); Jen-Yuan Chang, Hsinchu City (TW)

(73) Assignee: Taiwan Semiconductor Manufacturing Company, Ltd., Hsinchu (TW)

(21) Appl. No.: 18/926,341

(22) Filed: Oct. 25, 2024

(51) Int. Cl. H01L 21/67

(52) U.S. Cl. CPC H10P 72/0616; H10P 72/0404

(57) ABSTRACT

A wafer cleaning system including a stage, a defect inspection module and a defect remover is provided. The stage is configured to support a wafer. The defect inspection module is located above the stage and configured to detect a location of at least one defect on a surface of the wafer. The defect remover is located above the stage and configured to remove the at least one defect on the surface of the wafer according to the location of the at least one defect. In addition, a wafer detecting module and a wafer cleaning method are also provided.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area.

These smaller electronic components also require smaller packages that occupy less area than previous packages. Examples of the type of packages for semiconductors include quad flat packages (QFP), pin grid array (PGA) packages, ball grid array (BGA) packages, flip chips (FC) packages, three-dimensional integrated circuits (3DICs), wafer level packages (WLPs), package on package (PoP) devices and wafer on wafer (WoW) devices. There are many challenges related to WOW devices. One challenge is particles in the WoW bonding interface, which will cause large-area of bulges and cause a large-area drop of the SoIC (System on Integrated Circuit) structure in the subsequent process. This may result in scrapping the entire wafer. Although existing WoW bonding tool already has pre-clean module by wet clean, it is not possible to completely remove all defects on the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a wafer cleaning system in accordance with some embodiments.

FIG. 2A illustrates a wafer with a defect thereon.

FIG. 2B illustrates the defect inspection module of FIG. 1 detecting a surface of the wafer of FIG. 2A.

FIG. 2C illustrates the defect remover of FIG. 1 removing the defect on the surface of the wafer of FIG. 2B.

FIG. 2D illustrates the defect inspection module of FIG. 1 detecting the surface of the wafer of FIG. 2C again.

FIG. 3 is a flow chart illustrating a wafer cleaning method corresponding to the wafer cleaning system of FIG. 1.

FIG. 4 illustrates the defect inspection module and the optical detector of the defect inspection module of FIG. 2B move synchronously.

FIG. 5 illustrates the emitting direction of the light beam emitted from the light emitter of the defect inspection module of FIG. 2B is varied.

FIG. 6 illustrates the wafer of FIG. 2B is driven to moved relatively to the defect inspection module.

FIG. 7 illustrates one of steps of cleaning a wafer by a wafer cleaning system in accordance with some embodiments.

FIG. 8 illustrates one of steps of cleaning a wafer by a wafer cleaning system in accordance with some embodiments.

FIG. 9 illustrates one of steps of cleaning a wafer by a wafer cleaning system in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

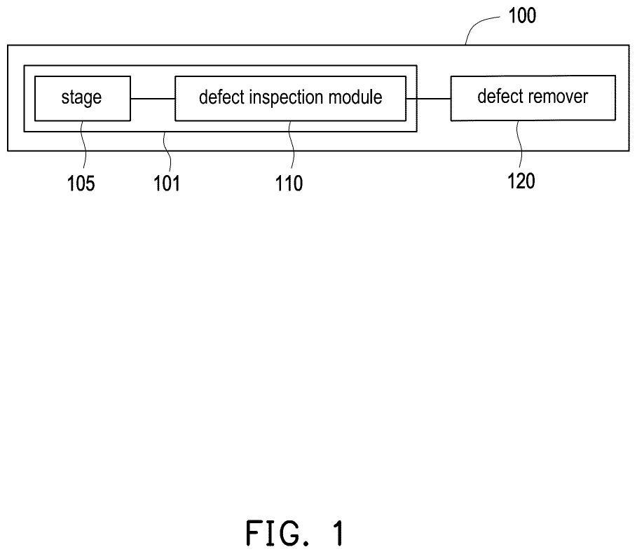

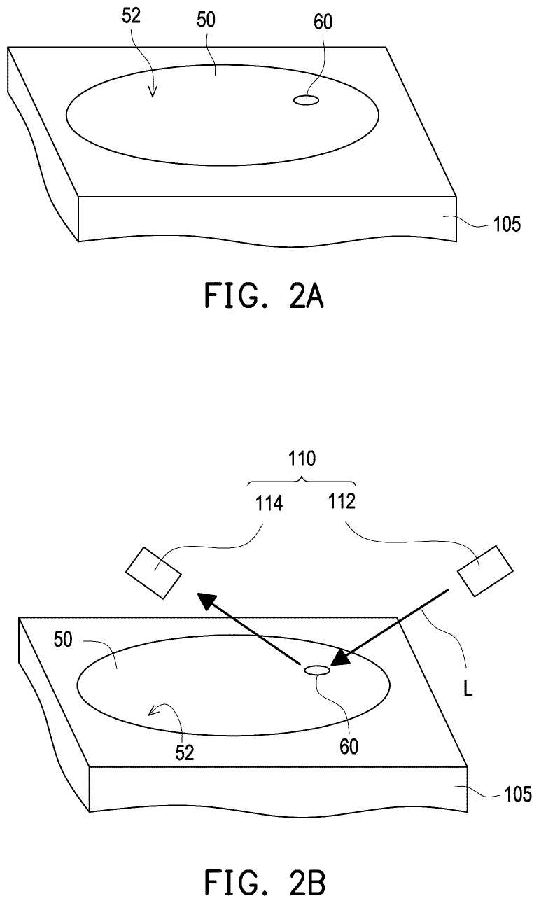

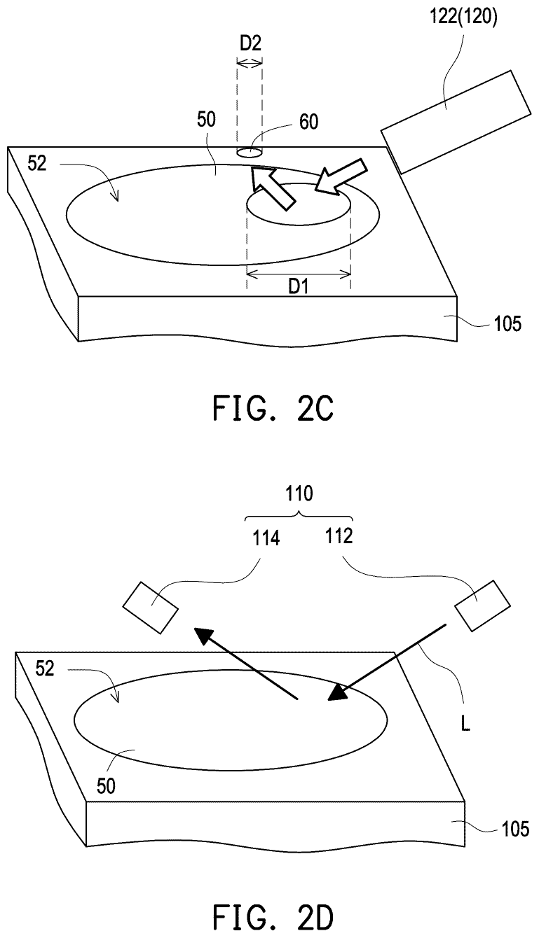

FIG. 1 is a schematic diagram illustrating a wafer cleaning system in accordance with some embodiments. FIG. 2A illustrates a wafer with a defect thereon. FIG. 2B illustrates the defect inspection module of FIG. 1 detecting a surface of the wafer of FIG. 2A. FIG. 2C illustrates the defect remover of FIG. 1 removing the defect on the surface of the wafer of FIG. 2B. FIG. 2D illustrates the defect inspection module of FIG. 1 detecting the surface of the wafer of FIG. 2C again. Referring to FIG. 1 and FIG. 2A to FIG. 2D, the wafer cleaning system 100 includes a wafer detecting module 101 and a defect remover 120. The wafer detecting module 101 includes a stage 105 and a defect inspection module 110. The stage 105 is configured to support a wafer 50. The defect inspection module 110 is located above the stage 105 and configured to move relatively to the stage 105 along a direction parallel to a surface 52 of the wafer 50 to detect defects (one defect 60 is illustrated) located at different regions on the surface 52 of the wafer 50 to obtain a defect information. The defect remover 120 is located above the stage 105 and configured to remove at least one defect 60 on the surface 52 of the wafer 50 according to the defect information. Specifically, each of the defect inspection module 110 and the defect remover 120 is, for example, driven to be located above the stage 105 by any suitable types of automated driving devices, and a suitable distance is maintained between the defect inspection module 110/defect remover 120 and the stage 110, and it is not limited thereto.

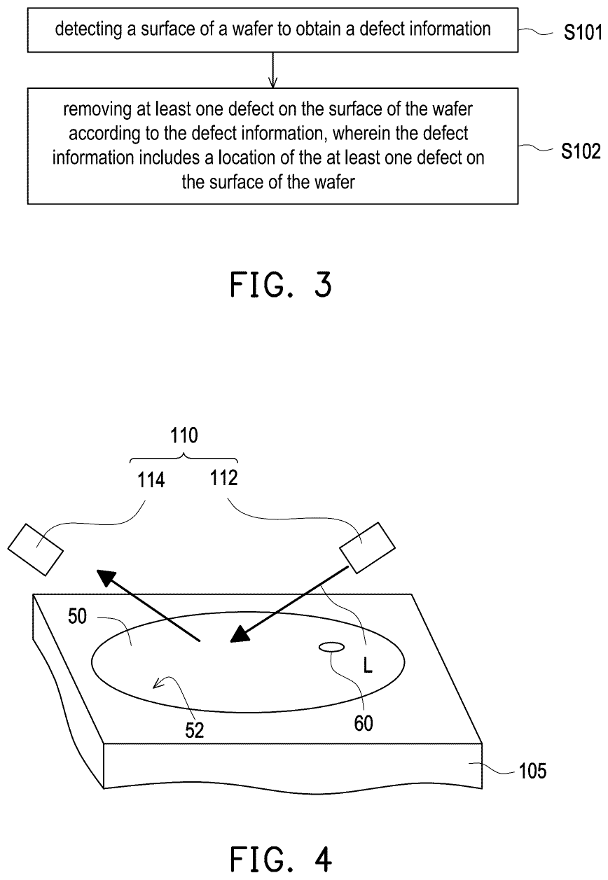

FIG. 3 is a flow chart illustrating a wafer cleaning method corresponding to the wafer cleaning system of FIG. 1. Referring to FIG. 2A to FIG. 2D and FIG. 3, specifically, a wafer cleaning method corresponding to the wafer cleaning system 100 shown in FIG. 1 includes at least the following steps. First, the surface 52 of the wafer 50 shown in FIG. 2A is detected by the defect inspection module 110 as shown in FIG. 2B to obtain the defect information, which is corresponding to the step S101 shown in FIG. 3. Then, the at least one defect 60 on the surface 52 of the wafer 50 is removed according to the defect information by the defect remover 120 as shown in FIG. 2C, wherein the defect information includes a location of the at least one defect 60 on the surface 52 of the wafer 50, which is corresponding to the step S102 shown in FIG. 3. In addition, after the step S102, the wafer 50 may be detected again by the defect inspection module 110 as shown in FIG. 2D to ensure that the surface 52 of the wafer 50 is entirely cleaned.

Specifically, the defect information, for example, includes a plurality of coordinates of the defects on the surface 52 of the wafer 50 detected by the defect inspection module 110, and the defect remover 120 is configured to be controlled to move to positions respectively corresponding to these coordinates in sequence, so as to remove the defects on the surface 52 of the wafer 50 in sequence.

In some embodiments, the defect remover 120 is coupled to the defect inspection module 110 to receive the defect information from the defect inspection module 110. In other embodiments, the defect remover 120 and the defect inspection module 110 are coupled to a control unit, such that the defect remover 120 is adapted to receive the defect information from the defect inspection module 110 through the control unit. The control unit is, for example, a computer device or the like.

In some embodiments, the defect information not only includes the location of the at least one defect 60 on the surface 52 of the wafer 50, but also includes a size of the at least one defect 60 on the surface 52 of the wafer 50 and a species of the at least one defect 60 on the surface 52 of the wafer 50. That is, the defect inspection module 110 is configured to detect the size of at least one defect 60 on the surface 52 of the wafer 50, the location of at least one defect 60 on the surface 52 of the wafer 50 and the species of at least one defect 60 on the surface 52 of the wafer 50, and the defect remover 120 is configured to remove the at least one defect 60 on the surface 52 of the wafer 50 according to the size of at least one defect 60 on the surface 52 of the wafer 50, the location of at least one defect 60 on the surface 52 of the wafer 50 and the species of the defect 60 on the surface 52 of the wafer 50.

In detail, the wafer cleaning system 100 is configured to determine the location (e.g., a coordinate on the surface 52) of the defect 60 on the surface 52 of the wafer 50 through a software operation, which performs an analysis to the detecting result of the defect inspection module 110, such that the defect remover 120 may perform the cleaning at the location on the surface 52 of the wafer 50 where the defect 60 exists. In addition, the wafer cleaning system 100 is configured to determine the size of the defect 60 on the surface 52 of the wafer 50 through a software operation, which performs the analysis to the detecting result of the defect inspection module 110, such that the defect remover 120 may perform the cleaning with a suitable range corresponding to the size of the defect 60 on the surface 52 of the wafer 50, so as to ensure that the defect 60 on the surface 52 of the wafer 50 is to be removed successfully under the cleaning performed by the defect remover 120. Further, the wafer cleaning system 100 is configured to determine the species of the defect 60 on the surface 52 of the wafer 50 through a software operation, which performs the analysis to the detecting result of the defect inspection module 110, so as to determine whether a cleaning to the defect 60 on the surface 52 of the wafer 50 is to be performed by the defect remover 120 or not. Specifically, the cleaning to the defect 60 on the surface 52 of the wafer 50 is to be performed by the defect remover 120 in a condition that the species of the defect 60 on the surface 52 of the wafer 50 is a particle or the like, and the cleaning to the defect 60 on the surface 52 of the wafer 50 is not to be performed by the defect remover 120 in a condition that the species of the defect 60 on the surface 52 of the wafer 50 is not a particle but is a concave or the like.

Based on the above-mentioned configuration and operation of the wafer cleaning system 100, the defects on the surface 52 of the wafer 50 can be significantly reduced. Therefore, large-area of bulges and a large-area drop of the SoIC (System on Integrated Circuit) structure in the subsequent process due to particles in the wafer on wafer (WoW) bonding interface can be prevented, so as to improve yield of the WoW devices.

In some embodiments, the defect inspection module 110 includes a light emitter 112 and an optical detector 114 as shown in FIG. 2B and FIG. 2D. The light emitter 112 of the defect inspection module 110 is, for example, a laser diode, a light emitting diode or other types of light emitting element, and is configured to emit a light beam L (e.g., a laser) toward the surface 52 of the wafer 50. The optical detector 114 of the defect inspection module 110 is configured to detect the light beam L reflected by the at least one defect 60, so as to determine the size of at least one defect 60 on the surface 52 of the wafer 50, to determine the location of at least one defect 60 on the surface 52 of the wafer 50 and to determine the species of at least one defect 60 on the surface 52 of the wafer 50.

In detail, an image of the surface 52 of the wafer 50 may be generated by the reflected light beams received by the optical detector 114, and then the image is analyzed in the software operation. Alternatively, as to determining the location of the defect 60, based on light reflection and scattering properties of the defect 60 and/or differences in light reflection and scattering properties between the defect 60 and the surface 52, the defect inspection module 110 may record a plurality of location information based on locations where the light beam L is reflected by the defects, and then the plurality of location information is transformed to a plurality of coordinates on the surface 52 of the wafer 50 under the software operation, such that the defect remover 120 is adapted to be driven to move to positions corresponding to the defects in sequence according to the coordinates. As to determining the size of the defect 60, the defect inspection module 110 may collect scattered light beams form the particles at different angles and analyze the scattering pattern for obtaining the particle size. As to determining the species of the defect 60, based on differences in light reflection and scattering properties between a particle and a concave, the species of the defect 60 may be determined based on the detecting result including light reflection and scattering properties of the defects. For example, reflected light beams with different light reflection and scattering properties are projected onto the optical detector, and then the difference of the light reflection and scattering properties may be reflected as voltage values.

FIG. 4 illustrates the defect inspection module and the optical detector of the defect inspection module of FIG. 2B move synchronously. In some embodiments, the light emitter 112 of the defect inspection module 110 and the optical detector 114 of the defect inspection module 110 may move synchronously above the wafer 50 as shown by FIG. 2B and FIG. 4 to entirely detect the surface 52 of the wafer 50 and to accurately detect the size of at least one defect 60 on the surface 52 of the wafer 50, the location of at least one defect 60 on the surface 52 of the wafer 50 and the species of at least one defect 60 on the surface 52 of the wafer 50.

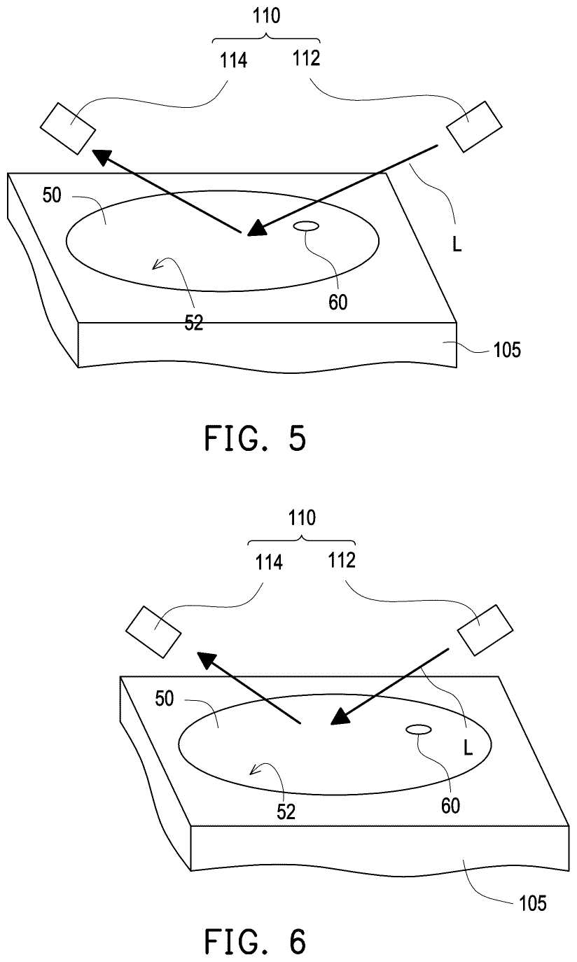

FIG. 5 illustrates the emitting direction of the light beam emitted from the light emitter of the defect inspection module of FIG. 2B is varied. Alternatively, in some embodiments, the emitting direction of the light beam L emitted from the light emitter 112 of the defect inspection module 110 may be varied as shown in FIG. 5 through the operation of lenses of the light emitter 112 of the defect inspection module 110, so as to vary where the light beam L reaches the surface 52 of the wafer 50. Correspondingly, the optical detector 114 of the defect inspection module 110 moves above the wafer 50 according to the emitting direction of the light beam L emitted from the light emitter 112 of the defect inspection module 110, so as to detect the light beam L reflected by the surface 52 of the wafer 50 and/or the light beam L reflected by the at least one defect 60.

FIG. 6 illustrates the wafer of FIG. 2B is driven to moved relatively to the defect inspection module. Alternatively, in some embodiments, the wafer 50 is driven to moved relatively to the light emitter 112 of the defect inspection module 110 and the optical detector 114 of the defect inspection module 110 while the light emitter 112 of the defect inspection module 110 and the optical detector 114 of the defect inspection module 110 are not moved, as shown in FIG. 6. Specifically, the wafer 50 may be carried on a movable stage and moved with the movable stage. In other embodiments, the wafer 50 may be driven to move by other manner and it is not limited thereto.

In some embodiments, the defect remover 120 includes a flushing unit 122 as shown in FIG. 2C. The flushing unit 122 of the defect remover 120 is configured to flush the surface 52 of the wafer 50 at the location of the at least one defect 60 on the surface 52 of the wafer 50. Specifically, a flushing range D1 (Shown in FIG. 2C) of the flushing unit 122 of the defect remover 120 may be greater than the size D2 (Shown in FIG. 2C) of the at least one defect 60, so as to ensure that the at least one defect 60 on the surface 52 of the wafer 50 is to be removed under the flushing performed by the flushing unit 122 of the defect remover 120. The type of the flushing performed by the flushing unit 122 of the defect remover 120 may be a wet rinse, an air purge or an ion purge, and it is not limited thereto. In addition, in other embodiments, the flushing range of the flushing unit 122 of the defect remover 120 may be equal to the size of the at least one defect 60 on the surface 52 of the wafer 50, and it is not limited thereto. In some embodiments, after the surface 52 of the wafer 50 is flushed by wet rinse, the cleaning fluid remaining on the surface 52 of the wafer 50 may be further removed to completely maintain the cleanliness of the surface 52 of the wafer 50.

In the embodiment of FIG. 2B, only one defect 60 exists on the surface 52 of the wafer 50. In other embodiments, the light emitter 112 of the defect inspection module 110 and the optical detector 114 of the defect inspection module 110 may be applied to detect two or more defects on the surface 52 of the wafer 50. For example, in a condition that two defects exist on the surface 52 of the wafer 50, during the process that the light emitter 112 of the defect inspection module 110 and the optical detector 114 of the defect inspection module 110 move synchronously above the wafer 50, the light emitter 112 of the defect inspection module 110 emits the light beam L (e.g., a laser) toward the surface 52 of the wafer 50 at the location of a first one of the defects and the optical detector 114 of the defect inspection module detects the light beam L reflected by the first one of the defects, so as to determine the size of the first one of the defects on the surface 52 of the wafer 50, to determine the location of the first one of the defects on the surface 52 of the wafer 50 and to determine the species of the first one of the defects on the surface 52 of the wafer 50, and then the light emitter 112 of the defect inspection module 110 emits the light beam L (e.g., a laser) toward the surface 52 of the wafer 50 at the location of a second one of the defects and the optical detector 114 of the defect inspection module detects the light beam L reflected by the second one of the defects, so as to determine the size of the second one of the defects on the surface 52 of the wafer 50, to determine the location of the second one of the defects on the surface 52 of the wafer 50 and to determine the species of the second one of the defects on the surface 52 of the wafer 50.

Similarly, in a condition that more than two defects exist on the surface 52 of the wafer 50, during the process that the light emitter 112 of the defect inspection module 110 and the optical detector 114 of the defect inspection module 110 move synchronously above the wafer 50, the light emitter 112 of the defect inspection module 110 emits the light beam L (e.g., a laser) toward the surface 52 of the wafer 50 at the locations of all of the defects in sequence and the optical detector 114 of the defect inspection module detects the light beam L reflected by all of the defects in sequence, so as to determine the size of each of the defects on the surface 52 of the wafer 50, to determine the location of each of the defects on the surface 52 of the wafer 50 and to determine the species of each of the defects on the surface 52 of the wafer 50.

In addition, in the embodiment of FIG. 2B, the light emitter 112 of the defect inspection module 110 and the optical detector 114 of the defect inspection module 110 are applied to detect the surface 52 of the single wafer 50. In other embodiments, the light emitter 112 of the defect inspection module 110 and the optical detector 114 of the defect inspection module 110 may be applied to detect surfaces of two or more wafers in sequence. Specifically, in a condition that the light emitter 112 of the defect inspection module 110 and the optical detector 114 of the defect inspection module 110 are applied to detect surfaces of two or more wafers, the light emitter 112 of the defect inspection module 110 and the optical detector 114 of the defect inspection module 110 may obtain defect information of the surfaces of all of the wafers in sequence, and then the wafer cleaning system 100 determines locations (e.g., coordinates on the surfaces 52) of the defects on the surfaces of all of the wafers through a software operation, which performs an analysis to the detecting results corresponding to all of the wafers.

In the embodiment of FIG. 2C, only one defect 60 exists on the surface 52 of the wafer 50. In other embodiments, the flushing unit 122 of the defect remover 120 may be applied to remove two or more defects on the surface 52 of the wafer 50. For example, in a condition that two defects exist on the surface 52 of the wafer 50, the flushing unit 122 of the defect remover 120 may flush the surface 52 of the wafer 50 at the location of a first one of the defects on the surface 52 of the wafer 50, and then the flushing unit 122 of the defect remover 120 may flush the surface 52 of the wafer 50 at the location of a second one of the defects on the surface 52 of the wafer 50. Similarly, in a condition that more than two defects exist on the surface 52 of the wafer 50, the flushing unit 122 of the defect remover 120 may flush the surface 52 of the wafer 50 at the locations of all of the defects on the surface 52 of the wafer 50 in sequence.

In addition, in the embodiment of FIG. 2C, the flushing unit 122 of the defect remover 120 is applied to flush the surface 52 of the single wafer 50. In other embodiments, the flushing unit 122 of the defect remover 120 may be applied to flush surfaces of two or more wafers in sequence.

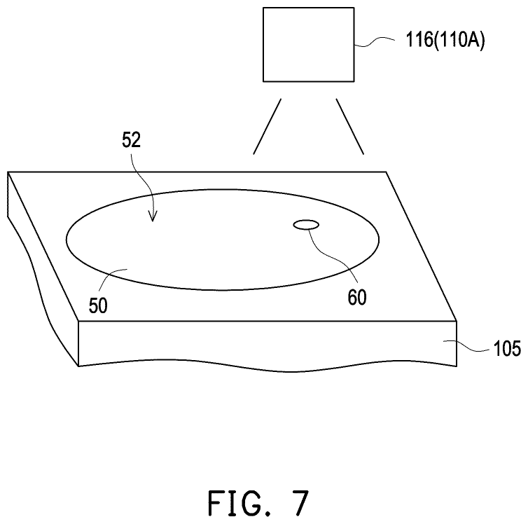

FIG. 7 illustrates one of steps of cleaning a wafer by a wafer cleaning system in accordance with some embodiments. Referring to FIG. 7, a difference between the embodiment shown in FIG. 7 and the embodiment shown in FIG. 2B is that, the defect inspection module 110A shown in FIG. 7 includes an image capturing unit 116 instead of the light emitter 112 of the defect inspection module 110 and the optical detector 114 of the defect inspection module 110 shown in FIG. 2B. The image capturing unit 116 of the defect inspection module 110A is, for example, a charge-coupled device (CCD) camera, a complementary metal-oxide-semiconductor camera (CMOS) or other types of cameras, and it is not limited thereto. The image capturing unit 116 of the defect inspection module 110A is configured to capture an image of the surface 52 of the wafer 50. If the at least one defect 60 exists on the surface 52 of the wafer 50, then an image of the defect 60 is to be included in the image of the surface 52 of the wafer 50 captured by the image capturing unit 116 of the defect inspection module 110A. The image of the surface 52 of the wafer 50 captured by the image capturing unit 116 of the defect inspection module 110A is, for example, to be analyzed through a software operation for determining the size, the location and the species of the defect 60 on the surface 52 of the wafer 50.

In the embodiment shown in FIG. 7, the image capturing unit 116 of the defect inspection module 110A is, for example, configured to capture an image of the entire surface 52 of the wafer 50 or configured to capture an image of a partial region of the surface 52 of the wafer 50, and it is not limited thereto. In addition, the image capturing unit 116 of the defect inspection module 110A is, for example, configured to be driven to move above the surface 52 of the wafer 50 for capturing images of the entire surface 52 of the wafer 50. Alternatively, in other embodiments, the defect inspection module 110A may includes a plurality of image capturing units 116 for respectively capturing a plurality of images of different regions of the surface 52 of the wafer 50.

In the embodiment of FIG. 7, only one defect 60 exists on the surface 52 of the wafer 50. In other embodiments, the image capturing unit 116 of the defect inspection module 110A may be applied to detect two or more defects on the surface 52 of the wafer 50. For example, in a condition that two defects exist on the surface 52 of the wafer 50, the image capturing unit 116 of the defect inspection module 110A may capture an image of the entire surface 52 of the wafer 50 to obtain the images of the two defects on the surface 52 of the wafer 50. Alternatively, the image capturing unit 116 of the defect inspection module 110A may capture a plurality of images respectively corresponding to partial regions of the surface 52 of the wafer 50, which includes the images of the two defects on the surface 52 of the wafer 50. Similarly, in a condition that more than two defects exist on the surface 52 of the wafer 50, the image capturing unit 116 of the defect inspection module 110A may capture an image of the entire surface 52 of the wafer 50 to obtain the images of all of the defects on the surface 52 of the wafer 50. Alternatively, the image capturing unit 116 of the defect inspection module 110A may capture a plurality of images respectively corresponding to partial regions of the surface 52 of the wafer 50, which includes the images of all of the defects on the surface 52 of the wafer 50.

In addition, in the embodiment of FIG. 7, the image capturing unit 116 of the defect inspection module 110A are applied to capture the image of the surface 52 of the single wafer 50. In other embodiments, the image capturing unit 116 of the defect inspection module 110A may be applied to capture images of surfaces of two or more wafers in sequence.

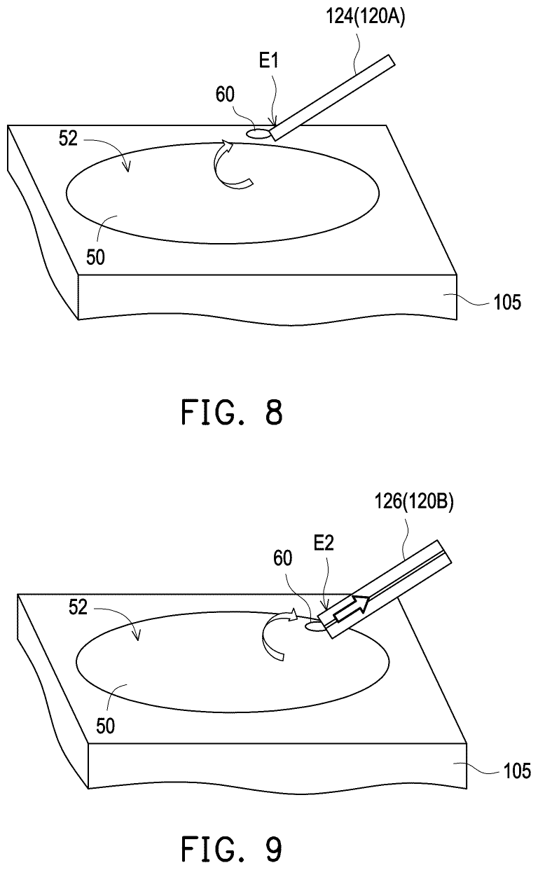

FIG. 8 illustrates one of steps of cleaning a wafer by a wafer cleaning system in accordance with some embodiments. Referring to FIG. 8, a difference between the embodiment shown in FIG. 8 and the embodiment shown in FIG. 2C is that, the defect remover 120A shown in FIG. 8 includes a particle picking unit 124 instead of the flushing unit 122 of the defect remover 120 shown in FIG. 2C. The particle picking unit 124 of the defect remover 120A is configured to pick the at least one defect 60 (e.g., a particle) on the surface 52 of the wafer 50. Specifically, the particle picking unit 124 of the defect remover 120A shown in FIG. 8 is, for example, a probe with an adhesive end E1 for adhering the at least one defect 60 (e.g., a particle).

In the embodiment of FIG. 8, only one defect 60 exists on the surface 52 of the wafer 50. In other embodiments, the particle picking unit 124 of the defect remover 120A may be applied to remove two or more defects on the surface 52 of the wafer 50. For example, in a condition that two defects exist on the surface 52 of the wafer 50, the particle picking unit 124 of the defect remover 120A may pick a first one of the defects (e.g., a particle) on the surface 52 of the wafer 50 according to the location of the first one of the defects by the adhesive end E1 thereof, and then the particle picking unit 124 of the defect remover 120A may pick a second one of the defects (e.g., a particle) on the surface 52 of the wafer 50 according to the location of the second one of the defects by the adhesive end E1 thereof. Similarly, in a condition that more than two defects exist on the surface 52 of the wafer 50, the particle picking unit 124 of the defect remover 120A may pick all of the defects (e.g., particles) on the surface 52 of the wafer 50 in sequence according to the locations of all of the defects by the adhesive end E1 thereof.

In addition, in the embodiment of FIG. 8, the particle picking unit 124 of the defect remover 120A are applied to pick the defects on the surface 52 of the single wafer 50. In other embodiments, the particle picking unit 124 of the defect remover 120A may be applied to pick defects on surfaces of two or more wafers in sequence.

FIG. 9 illustrates one of steps of cleaning a wafer by a wafer cleaning system in accordance with some embodiments. Referring to FIG. 9, a difference between the embodiment shown in FIG. 9 and the embodiment shown in FIG. 2C is that, the defect remover 120B shown in FIG. 9 includes a particle picking unit 126 instead of the flushing unit 122 of the defect remover 120 shown in FIG. 2C. The particle picking unit 126 of the defect remover 120B is configured to pick the at least one defect 60 (e.g., a particle) on the surface 52 of the wafer 50. Specifically, the particle picking unit 126 of the defect remover 120B shown in FIG. 9 is, for example, a straw with an absorption end E2 for absorbing the at least one defect 60 (e.g., a particle). The particle picking unit 126 is, for example, connected to a vacuum adsorption device, such that the vacuum adsorption device may be perform vacuum adsorption to the defect 60 (e.g., a particle) through the particle picking unit 126 to remove the defect 60 (e.g., a particle) from the surface 52 of the wafer 50.

In the embodiments of FIG. 9, only one defect 60 exists on the surface 52 of the wafer 50. In other embodiments, the particle picking unit 124 of the defect remover 120A may be applied to remove two or more defects on the surface 52 of the wafer 50. For example, in a condition that two defects exist on the surface 52 of the wafer 50, the particle picking unit 126 of the defect remover 120B may pick a first one of the defects (e.g., a particle) on the surface 52 of the wafer 50 according to the location of the first one of the defects by the absorption end E2 thereof, and then the particle picking unit 126 of the defect remover 120B may pick a second one of the defects (e.g., a particle) on the surface 52 of the wafer 50 according to the location of the second one of the defects by the absorption end E2 thereof. Similarly, in a condition that more than two defects exist on the surface 52 of the wafer 50, the particle picking unit 126 of the defect remover 120B may pick all of the defects (e.g., particles) on the surface 52 of the wafer 50 in sequence according to the locations of all of the defects by the absorption end E2 thereof.

In addition, in the embodiment of FIG. 9, the particle picking unit 126 of the defect remover 120B are applied to pick the defects on the surface 52 of the single wafer 50. In other embodiments, the particle picking unit 126 of the defect remover 120B may be applied to pick defects on surfaces of two or more wafers in sequence.

In summary, based on the configurations and operations of the wafer cleaning system, wafer detecting module and wafer cleaning method in the embodiments, the defects on the surface of the wafer can be significantly reduced. Therefore, large-area of bulges and a large-area drop of the SoIC (System on Integrated Circuit) structure in the subsequent process due to particles in the wafer on wafer (WoW) bonding interface can be prevented, so as to improve yield of the WoW devices.

In accordance with some embodiments, a wafer cleaning system includes a stage, a defect inspection module and a defect remover. The stage is configured to support a wafer. The defect inspection module is located above the stage and configured to detect a location of at least one defect on a surface of the wafer. The defect remover is located above the stage and configured to remove the at least one defect on the surface of the wafer according to the location of the at least one defect.

In accordance with some embodiments, a wafer detecting module includes a stage and a defect inspection module. The stage is configured to support a wafer. The defect inspection module is located above the stage and configured to move relatively to the stage to detect defects located at different regions on a surface of the wafer.

In accordance with some embodiments, a wafer cleaning method includes at least the following steps. A surface of a wafer is detected to obtain a defect information. At least one defect on the surface of the wafer is removed according to the defect information, wherein the defect information includes a location of the at least one defect on the surface of the wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A wafer cleaning system, comprising:
a stage, configured to support a wafer;
a defect inspection module located above the stage and configured to detect a location of at least one defect on a surface of the wafer; and
a defect remover, located above the stage and configured to remove the at least one defect on the surface of the wafer according to the location of the at least one defect.

2. The wafer cleaning system of claim 1, wherein the defect inspection module is further configured to detect a size of the at least one defect on the surface of the wafer, and the defect remover is configured to remove the at least one defect on the surface of the wafer further according to the size of the at least one defect.

3. The wafer cleaning system of claim 1, wherein the defect inspection module is further configured to detect a species of the at least one defect on the surface of the wafer, and the defect remover is configured to remove the at least one defect on the surface of the wafer further according to the species of the at least one defect.

4. The wafer cleaning system of claim 1, wherein the defect inspection module comprises a light emitter and an optical detector, the light emitter is configured to emit a light beam toward the surface of the wafer, and the optical detector is configured to detect the light beam reflected by the at least one defect.

5. The wafer cleaning system of claim 1, wherein the defect inspection module comprises an image capturing unit, and the image capturing unit is configured to capture an image of the surface of the wafer.

6. The wafer cleaning system of claim 1, wherein the defect remover comprises a flushing unit, and the flushing unit is configured to flush the surface of the wafer at the location of the at least one defect.

7. The wafer cleaning system of claim 6, wherein a flushing range of the flushing unit is greater than a size of the at least one defect or equal to the size of the at least one defect.

8. The wafer cleaning system of claim 1, wherein the at least one defect comprises at least one particle on the surface of the wafer, the defect remover comprises a particle picking unit, and the particle picking unit is configured to pick the at least one particle on the surface of the wafer.

9. A wafer detecting module, comprising:
a stage, configured to support a wafer; and
a defect inspection module, located above the stage and configured to move relatively to the stage to detect defects located at different regions on a surface of the wafer.

10. The wafer detecting module of claim 9, wherein the defect inspection module comprises a light emitter and an optical detector, the light emitter is configured to emit a light beam toward the surface of the wafer, and the optical detector is configured to detect the light beam reflected by each of the defects.

11. The wafer detecting module of claim 9, wherein the defect inspection module comprises an image capturing unit, and the image capturing unit is configured to capture an image of the surface of the wafer.

12. The wafer detecting module of claim 9, wherein the defect inspection module is configured to detect a location, a size or a species of each of the defects on the surface of the wafer.

13. The wafer detecting module of claim 9, wherein the defect inspection module is configured to move along a direction parallel to the surface of the wafer.

14. A wafer cleaning method, comprising:
detecting a surface of a wafer to obtain a defect information; and
removing at least one defect on the surface of the wafer according to the defect information,
wherein the defect information comprises a location of the at least one defect on the surface of the wafer.

15. The wafer cleaning method of claim 14, wherein the defect information further comprises a size of the at least one defect on the surface of the wafer.

16. The wafer cleaning method of claim 14, wherein the defect information further comprises a species of the at least one defect on the surface of the wafer.

17. The wafer cleaning method of claim 14, wherein detecting the surface of the wafer comprises emitting a light beam toward the surface of the wafer and detecting the light beam reflected by the at least one defect.

18. The wafer cleaning method of claim 14, wherein detecting the surface of the wafer comprises capturing an image of the surface of the wafer.

19. The wafer cleaning method of claim 14, wherein removing the at least one defect on the surface of the wafer comprises flushing the surface of the wafer at the location of the at least one defect.

20. The wafer cleaning method of claim 14, wherein the at least one defect comprises at least one particle on the surface of the wafer, and removing the at least one defect on the surface of the wafer comprises picking the at least one particle on the surface of the wafer.
